(19) United States
(12) Patent Application Publication
(10) Pub. No.: US 2026/0113845 A1
(43) Pub. Date: Apr. 23, 2026

(54) PRINTED CIRCUIT BOARD

(71) Applicant: SAMSUNG ELECTRO-MECHANICS CO., LTD., Suwon-si (KR)

(72) Inventors: Sang Hyuk SON, Suwon-si (KR); Jung Yub KIM, Suwon-si (KR)

(73) Assignee: SAMSUNG ELECTRO-MECHANICS CO., LTD., Suwon-si (KR)

(21) Appl. No.: 19/246,054

(22) Filed: Jun. 23, 2025

(30) Foreign Application Priority Data
Oct. 18, 2024 (KR) 10-2024-0142937

(51) Int. Cl. H05K 1/11

(52) U.S. Cl. CPC H05K 1/116; H05K 2201/09536

(57) ABSTRACT

A printed circuit board is disclosed, comprising a first insulating layer having opposing first and second surfaces in a thickness direction. A conductive via is disposed within a through-hole extending in the thickness direction of the first insulating layer. A first pad is positioned on the first surface of the first insulating layer and includes a first conductor layer and a second conductor layer, with the second conductor layer being disposed on the first conductor layer and the conductive via. The conductive via extends outward from the first surface of the first insulating layer beyond the first conductor layer.

### CROSS-REFERENCE TO RELATED APPLICATIONS

This application claims the benefit of priority to Korean Patent Application No. 10-2024-0142937 filed on Oct. 18, 2024 in the Korean Intellectual Property Office, the disclosures of which are incorporated herein by reference in its entirety.

### BACKGROUND

### 1. Field

The present disclosure relates to a printed circuit board.

### 2. Description of Related Art

In order to respond to the recent trend for lighter and smaller mobile devices, the need to implement lighter and thinner printed circuit boards mounted thereon is also gradually increasing. Meanwhile, as mobile devices have become lighter and thinner, an undercut phenomenon may occur during the process of implementing fine circuits, which can cause fine circuit defects. In response to this technical demand, research is continuously being performed to implement a circuit having a fine line width and spacings with improving reliability.

### SUMMARY

An example embodiment of the present disclosure is to provide a printed circuit board on which a circuit having a fine line width and spacings may be implemented.

According to an example embodiment, a printed circuit board includes a first insulating layer having first and second surfaces opposing each other in a thickness direction; a conductive via disposed in a through-hole formed in the thickness direction in the first insulating layer; and a first pad disposed on a side of the first surface of the first insulating layer and including a first conductor layer and a second conductor layer disposed on the first conductor layer and the conductive via, wherein the conductive via has a form protruding further outwardly of the first insulating layer from the first surface than the first conductor layer.

The conductive via may be connected to the second conductor layer, and the first conductor layer may surround a side surface of the conductive via.

A region of the second conductor layer corresponding to the conductive via may have a protruding shape.

An inner conductor layer disposed between an inner wall of the through-hole and the conductive via may be further included.

The conductive via may have a form protruding further outwardly of the first insulating layer from the first surface than the inner conductor layer.

The inner conductor layer may form an interface with the first conductor layer and may be in contact with the first conductor layer.

The inner conductor layer may form an interface with the second conductor layer and may be in contact with the second conductor layer.

A side surface of the inner conductor layer may be in contact with a side surface of the first conductor layer.

An upper surface of the inner conductor layer and an upper surface of the first conductor layer may form a coplanar surface.

An upper surface of the inner conductor layer and an upper surface of the first conductor layer may be in contact with a lower surface of the second conductor layer.

The inner conductor layer may not cover an upper surface of the first conductor layer.

The inner conductor layer may include first and second inner conductor layers, wherein the first inner conductor layer may be disposed closer to an inner wall of the through-hole than the second inner conductor layer.

The conductive via may extend further outward from the first surface of the first insulating layer than the first and second inner conductor layers.

A thickness of the first conductor layer may be 0.5 μm or more and 2 μm or less.

A distance protruding laterally from the through-hole of the first insulating layer in the first pad may be 25 μm or less.

### BRIEF DESCRIPTION OF DRAWINGS

The above and other aspects, features, and advantages of the present disclosure will become more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating an example of a printed circuit board;

FIG. 4 is an enlarged view of a portion of FIG. 3;

FIG. 5 is a cross-sectional view schematically illustrating another example of a printed circuit board; and

FIGS. 6 to 14 illustrate examples of a method for manufacturing a printed circuit board.

### DETAILED DESCRIPTION

Hereinafter, embodiments of the present disclosure will be described as follows with reference to the attached drawings. The present disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art. Accordingly, shapes and sizes of elements in the drawings may be exaggerated for clear description, and elements indicated by the same reference numerals are the same elements in the drawings.

### Electronic Device

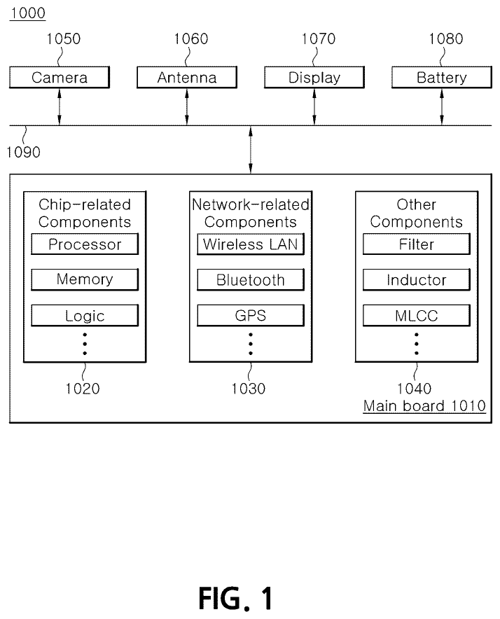

FIG. 1 is a block diagram schematically illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, and may also include other types of chip related components. Also, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, and may also include a variety of other wireless or wired standards or protocols. Also, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, and may also include passive components used for various other purposes, or the like. Also, other components 1040 may be combined with each other, together with the chip related components 1020 and/or the network related components 1030 described above.

Depending on a type of the electronic device 1000, the electronic device 1000 may include other components which may or may not be physically or electrically connected to the mainboard 1010. The other components may include, for example, a camera module 1050, an antenna module 1060, a display 1070, and a battery 1080. However, the other components are not limited thereto, and may include an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. The other components may also include other components used for various purposes depending on a type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game console, a smartwatch, an automotive component, or the like. However, the electronic device 1000 is not limited thereto, and may be any other electronic device processing data.

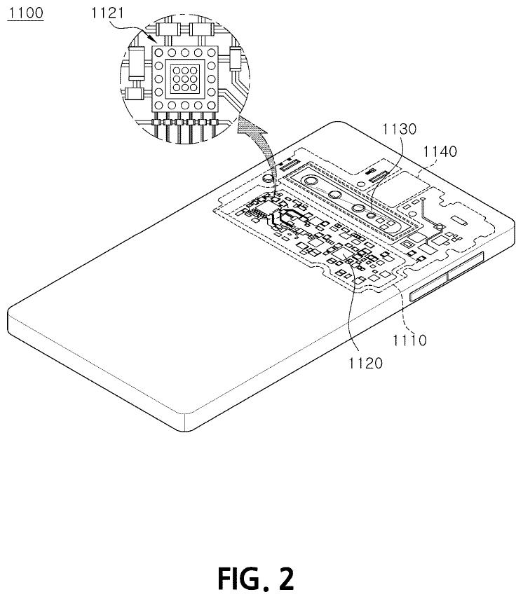

FIG. 2 is a perspective view schematically illustrating an example of an electronic device.

Referring to FIG. 2, an electronic device may be a smartphone 1100. A motherboard 1110 may be accommodated in the smartphone 1100, and various components 1120 may be physically or electrically connected to the motherboard 1110. Also, other components which may or may not be physically or electrically connected to the motherboard 1110, such as a camera module 1130, may be accommodated in the body 1101. A portion of the components 1120 may be the chip related components, such as, for example, a component package 1121, but an example embodiment example thereof is not limited thereto. The component package 1121 may have the form of a printed circuit board on which electronic components including active components and/or passive components are surface-mounted. Alternatively, the component package 1121 may be configured in the form of a printed circuit board in which active components and/or passive components are buried. The electronic device is not necessarily limited to the smartphone 1100, and may be other electronic devices as described above.

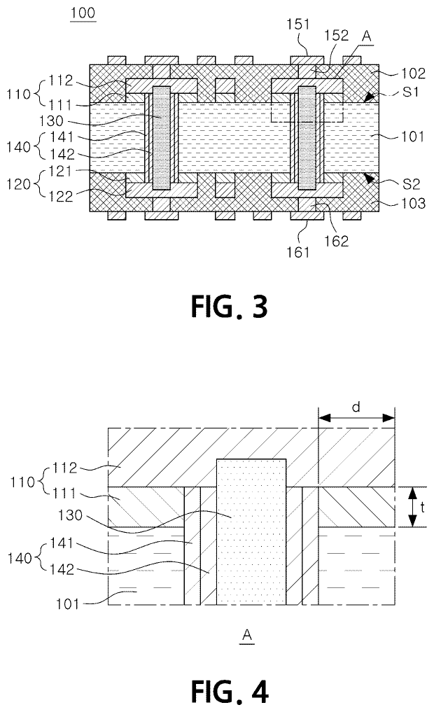

FIG. 3 is a cross-sectional view schematically illustrating an example of a printed circuit board, and FIG. 4 is an enlarged view of a portion of FIG. 3. Referring to FIGS. 3 and 4, a printed circuit board 100 according to the present embodiment includes a first insulating layer 101, a conductive via 130, and a first pad 110 including a first conductor layer 111 and a second conductor layer 112. Here, the conductive via 130 extends further outward(toward an upper side based on the illustrated form) from the first surface S1 of the first insulating layer 101 than the first conductor layer 111. When the conductive via 130 protrudes further than the first conductor layer 111 and the second conductor layer 112 is connected thereto, the electrical and physical contact properties between the conductive via 130 and the first pad 110 may be improved. In addition, such a structure is suitable for miniaturizing the conductive via 130, the first conductor layer 111, the second conductor layer 112, or the like, and reducing the pitch. Hereinafter, the main components of the printed circuit board may be described in greater detail.

The first insulating layer 101 may be a core insulating layer. The first insulating layer 101 may include an insulating material such as an insulating resin, such as a thermosetting resin such as an epoxy resin or a thermoplastic resin such as a polyimide, or a material in which the resins are mixed with an inorganic filler such as silica, or a resin impregnated into a core material such as glass fiber, glass cloth, glass fabric, or the like, together with an inorganic filler, for example, copper clad laminate (CCL), but an example embodiment thereof is not limited thereto. The first insulating layer 101 has a first surface S1 and a second surface S2 opposing each other in a thickness direction (a vertical direction based on the illustrated form). In addition, a through-hole (H in FIG. 6) is formed in the thickness direction in the first insulating layer 101. The first insulating layer 101 may be thicker than the insulating layers 102 and 103 respectively disposed on the sides of the first surface S1 and the second surface S2. In this case, the thicknesses of respective layers may be measured using a scanning microscope or an optical microscope based on a polished or cut cross-section of the printed circuit board in a vertical direction. When the thickness is not constant, the thickness relationship may be compared by using an average value of the thickness of each object measured at five arbitrary points.

A second insulating layer 102 may be disposed on the side of the first surface S1, and a third insulating layer 103 may be disposed on the side of the second surface S2. In this case, the second and third insulating layers 102 and 103 may be build-up insulating layers. Each of the second and third insulating layers 102 and 103 may include a plurality of build-up insulating layers, and in this case, the plurality of build-up insulating layers may be integrated with each other without boundaries or may be separated from each other. As an example of an insulating material that can be included in the second and third insulating layers 102 and 103, an insulating resin such as a thermosetting resin such as an epoxy resin or a thermoplastic resin such as a polyimide, or a material in which the resins are mixed with an inorganic filler such as silica, or a resin impregnated into a core material such as glass fiber, glass cloth, glass fabric, or the like, together with an inorganic filler, for example, Ajinomoto build-up film (ABF), prepreg, or the like may be used, but an example embodiment thereof is not limited thereto.

A conductive via 130 may be disposed in a through-hole formed in the thickness direction in the first insulating layer 101, and a first pad 110 and a second pad 120 may be connected to each other by the conductive via 130. In addition, an inner conductor layer 140 may be disposed between an inner wall of the through-hole of the first insulating layer 101 and the conductive via 130, and in this case, the inner conductor layer 140 may include a plurality of conductor layers, for example, a first inner conductor layer 141 and a second inner conductor layer 142. Here, the first inner conductor layer 141 may be disposed closer to the inner wall of the through-hole of the first insulating layer 101 than the second inner conductor layer 142.

The conductive via 130 may include a metal material such as copper (Cu), aluminum (Al), silver (Ag), tin (Sn), gold (Au), nickel (Ni), lead (Pb), titanium (Ti), or an alloy thereof, and may perform various functions depending on the design of a corresponding layer. For example, the conductive via 130 may include a ground pattern, a power pattern, a signal pattern, or the like. In an example, a conductive via 130 may be formed by filling a plug into the through-hole after the inner conductor layer 140 is formed by plating. The conductive via 130 may have a roughly circular or elliptical shape based on a planar shape viewed from above. In addition, in terms of securing adhesion by increasing a specific surface area, the conductive via 130 may have a polygonal shape on a plane, as well as a so-called flower shape in which multiple circles or ovals are overlapped.

A first pad 110 is disposed on the side of the first surface S1, and includes a first conductor layer 111 and a second conductor layer 112. Here, a second conductor layer 112 is disposed on the first conductor layer 111 and the conductive via 130. A second pad 120 may be disposed on the side of the second surface S2 of the first insulating layer 101, and the second pad 120 may include a third conductor layer 121 and a fourth conductor layer 122. The second pad 120 may be implemented in the same form as the first pad 110, and the structure of the first pad 110 and the conductive via 130 on the side of the first surface S1 of the first insulating layer 101 is described below, but the description may also be applied to the second pad 120 and the conductive via 130 disposed on the side of the second surface S2 of the first insulating layer 101.

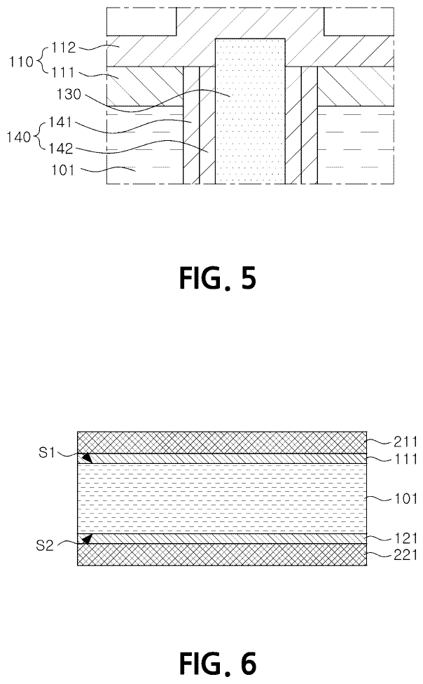

In the present embodiment, the conductive via 130 has a form protruding further outwardly of the first insulating layer 101 from the first surface S1 than the first conductor layer 111. Accordingly, as can be seen in the enlarged view of FIG. 4, a conductive via 130 may be connected to the second conductor layer 112, and a structure in which the first conductor layer 111 surrounds a side surface of the conductive via 130 may be obtained. In this case, although it is illustrated that an upper surface of the second conductor layer 112 has a flat structure in FIGS. 3 and 4, the upper surface of the second conductor layer 112 may have a protruding structure. That is, as in the modified example of FIG. 5, a region of the second conductor layer 112 corresponding to the conductive via 130 may have a protruding shape.

Referring to FIGS. 3 and 4, the shapes of the first pad 110 and the conductive via 130 will be described in a greater detail. As described above, the inner conductor layer 140 may be provided on an inner wall of the through-hole as a plating layer. In this case, as in the illustrated form, the conductive via 130 may have a form protruding further outwardly of the first insulating layer 101 from the first surface S1 than the inner conductor layer 140. The inner conductor 140 may include first and second inner conductor layers 141 and 142, and in this case, the conductive via 130 may have a form protruding further outwardly of the first insulating layer 101 from the first surface S1 than the first and second conductor layers 141 and 142.

Meanwhile, the inner conductor layer 140 may form an interface with the first conductor layer 111 and may be in contact with the first conductor layer 111. As a more specific example, a side surface of the inner conductor layer 140 may be in contact with a side surface of the first conductor layer 111. The inner conductor layer 140 may form an interface with the second conductor layer 112 and may be in contact with the second conductor layer 112. In addition, as shown in the illustrated form, an upper surface of the inner conductor layer 140 and an upper surface of the first conductor layer 111 may form a coplanar surface, and in this case, the upper surface of the inner conductor layer 140 and the upper surface of the first conductor layer 111 may also be in contact with a lower surface of the second conductor layer 112. This type of coplanar structure can be obtained by performing a process of polishing the conductor layers disposed above the first conductor layer 111 and the inner conductor layer 140, as described later. In addition, the inner conductor layer 140 may contact the side surface of the first conductor layer 111 while not covering the upper surface of the first conductor layer 111.

As described above, in the present embodiment, the inner conductor layer 140 may be formed through a separate process, for example, a separate plating process, rather than being formed integrally with the first conductor layer 111 or the second conductor layer 112, so that the inner inductor layer 140 and the conductor layers 111 and 112 may form an interface and may be in contact with each other. When the inner conductor layer 140 and the second conductor layer 112 are plated at the same time and implemented integrally with each other, it may be difficult to implement a fine circuit in a subsequent etching process. In this embodiment, the inner conductor layer 140 may be formed separately from the first conductor layer 111 or the second conductor layer 112, so that the first pad 110 may be formed to have a thin and narrow width even after etching, and accordingly, a greater number of conductive vias 130 may be disposed in a space of the same size. Specifically, a thickness (t) of the first conductor layer 111 may be 0.5 μm or more and 2 μm or less, and in addition, a distance (d) protruding laterally from the through-hole of the first insulating layer 101 in the first pad 110 may be reduced to a level of 25 μm or less. Accordingly, the size of the first pad 110 may be reduced and the alignment with the conductive via 130 may be improved. Furthermore, a spacing between the conductive vias 130 may also be made finer, for example, the spacing between adjacent conductive vias 130 may be implemented at a level of 300 μm or less.

Meanwhile, when describing additional configurations of the printed circuit board 100, conductor patterns 151 and 161 may be respectively disposed on the first pad 110 and the second pad 120, and in addition thereto, conductor patterns may also be disposed at the same level as the first pad 110 and the second pad 120. In this case, vias 152 and 162 respectively connecting the first and second pads 110 and 120 and the conductor patterns 151 and 161 may be provided.

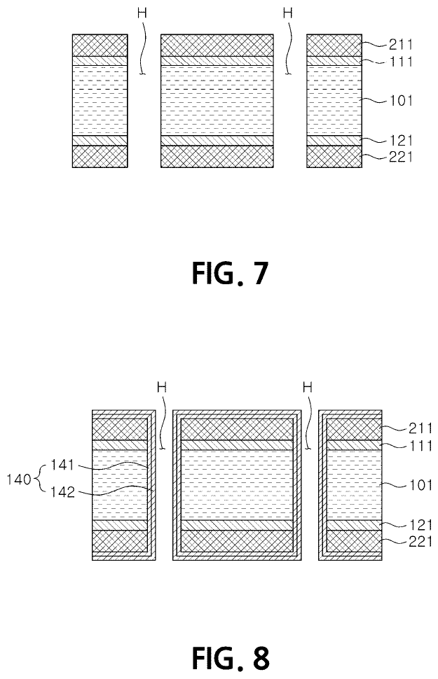

Hereinafter, an example of a method for manufacturing a printed circuit board will be described with reference to FIGS. 6 to 14. First, referring to FIGS. 6 and 7, a first insulating layer 101 is prepared and a through-hole H penetrating through the first insulating layer 101 in a thickness direction is formed. Here, conductor layers 111 and 121 may be disposed on a first surface S1 and a second surface S2 of the first insulating layer 101, respectively, and the conductor layers 111 and 121 may become a first conductor layer 111 and a third conductor layer 121, respectively, through a subsequent process. In addition, sacrificial layers 211 and 221 may be disposed to cover each of the conductor layers 111 and 121. As an example, the conductor layers 111 and 121 may be copper foil, and the sacrificial layers 211 and 221 may be plating layers. The through-hole H of the first insulating layer 101 may be formed by an appropriate processing method, for example, laser processing, and then subjected to a desmear process.

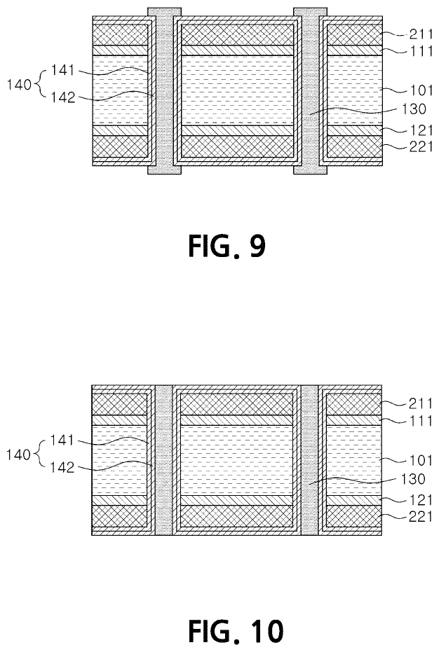

Next, as illustrated in the form of FIG. 8, an inner conductor layer 140 may be formed in the through-hole H of the first insulating layer 101, and the inner conductor layer 140 may also be formed on a side of the first surface S1 and a side of the second surface S2 of the first insulating layer in addition to the through-hole H. The inner conductor layer 140 may include a first inner conductor layer 141 and a second inner conductor layer 142. In this case, the first inner conductor layer 141 may be formed by electroless plating, and the second inner conductor layer 142 may be formed by electrolytic plating. Subsequently, referring to FIGS. 9 and 10, a conductive via 130 is formed using a process such as filling a plug into the through-hole H of the first insulating layer 101, and in addition thereto, a plating process that can be used in the relevant technical field may also be used. Thereafter, if necessary, a region of the conductive via 130 protruding outwardly as illustrated in FIG. 10 may be removed through a polishing process.

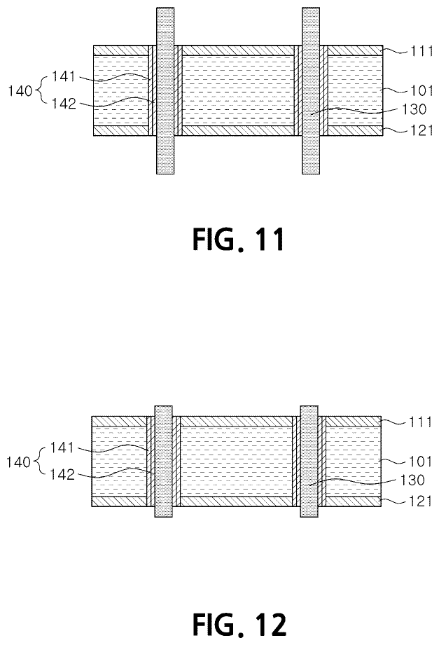

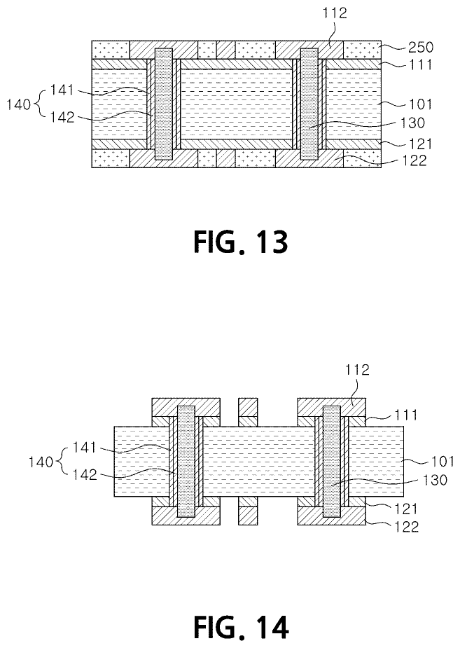

Next, as illustrated in the form of FIG. 11, the sacrificial layers 211 and 221 may be removed, and accordingly, at least a portion of a region of the inner conductor layer 140 covering the first surface S1 and the second surface S2 may be removed. In addition, a side surface of the conductive via (130) may be exposed by the process. A region protruding in a vertical direction from the conductive via 130 may be left as is, or alternatively, a portion thereof may be removed to adjust a height of the protrusion, as illustrated in FIG. 12. Referring to FIGS. 13 and 14, thereafter, conductor layers 112 and 122 may be formed, each of which may correspond to the second conductor layer 112 and fourth conductor layer 122 described above. As an example of the process, the conductor layers 112 and 122 may be formed by forming a mask layer 250 and then performing pattern plating on the open region. Thereafter, the mask layer 250 may be removed, and portions of the conductor layers 111, 112, 121, and 122 may be removed through an etching process to obtain a first pad 110 and a second pad 120 having the above-described structure (FIG. 13). Thereafter, a printed circuit board having the above-described type may be obtained through an appropriate build-up process.

In the present disclosure, the term cross-section may refer to a cross-sectional shape when an object is cut vertically, or a cross-sectional shape when the object is viewed from the side. Furthermore, the term plane may refer to a planar shape when the object is horizontally cut, or a planar shape when the object is viewed from the top or the bottom.

In the present disclosure, the terms an upper side, an upper portion, and an upper surface are used to refer to a downward direction with respect to a cross-section of a drawing, and a lower side, a lower portion, and a lower surface are used to refer to an opposite direction thereof. However, this is a definition of direction for the convenience of explanation, and the scope of the claim is not specifically limited by the description of this direction, and the concept of upper/lower may be changed at any time.

In the present disclosure, the term connected is a concept including not only directly connected but also indirectly connected through an adhesive layer or the like. Furthermore, a meaning of electrically connected is a concept including both physically connected and not connected. In addition, expressions such as first and second are used to distinguish one component from another, and do not limit the order and/or importance of the components. In some cases, a first component may be referred to as a second component without departing from the scope of rights, or similarly, the second component may be referred to as the first component.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

As set forth above, a printed circuit board according to an embodiment of the present disclosure may be provided with a circuit having a fine line width and spacings.

While the example embodiments have been illustrated and described above, it will be apparent to those skilled in the art that modifications and variations could be made without departing from the scope of the present disclosure as defined by the appended claims.

What is claimed is:

1. A printed circuit board, comprising:
a first insulating layer having first and second surfaces opposing each other in a thickness direction;
a conductive via disposed in a through-hole formed in the thickness direction in the first insulating layer; and
a first pad disposed on a side of the first surface of the first insulating layer and including a first conductor layer and a second conductor layer disposed on the first conductor layer and the conductive via,
wherein the conductive via extends further outward from the first surface of the first insulating layer than the first conductor layer.

2. The printed circuit board of claim 1, wherein the conductive via is connected to the second conductor layer, and
the first conductor layer surrounds a side surface of the conductive via.

3. The printed circuit board of claim 2, wherein a region of the second conductor layer corresponding to the conductive via has a protruding shape.

4. The printed circuit board of claim 1, further comprising:
an inner conductor layer disposed between an inner wall of the through-hole and the conductive via.

5. The printed circuit board of claim 4, wherein the conductive via protrudes further outward from the first surface of the first insulating layer than the inner conductor layer.

6. The printed circuit board of claim 4, wherein the inner conductor layer forms an interface with the first conductor layer and is in contact with the first conductor layer.

7. The printed circuit board of claim 4, wherein the inner conductor layer forms an interface with the second conductor layer and is in contact with the second conductor layer.

8. The printed circuit board of claim 4, wherein a side surface of the inner conductor layer is in contact with a side surface of the first conductor layer.

9. The printed circuit board of claim 8, wherein an upper surface of the inner conductor layer and an upper surface of the first conductor layer are coplanar.

10. The printed circuit board of claim 9, wherein the upper surface of the inner conductor layer and the upper surface of the first conductor layer are in contact with a lower surface of the second conductor layer.

11. The printed circuit board of claim 8, wherein the inner conductor layer does not cover the upper surface of the first conductor layer.

12. The printed circuit board of claim 4, wherein the inner conductor layer includes first and second inner conductor layers, wherein the first inner conductor layer is disposed closer to an inner wall of the through-hole than the second inner conductor layer.

13. The printed circuit board of claim 12, wherein the conductive via protrudes further outward from the first surface of the first insulating layer than the first and second inner conductor layers.

14. The printed circuit board of claim 1, wherein the first conductor layer has a thickness of 0.5 μm or more and 2 μm or less.

15. The printed circuit board of claim 1, wherein a distance protruding laterally from the through-hole of the first insulating layer in the first pad is 25 μm or less.

16. A printed circuit board, comprising:
a first insulating layer having first and second surfaces opposing each other in a thickness direction;
a through-hole extending through the first insulating layer in the thickness direction;
an inner conductor layer disposed on an inner wall of the through-hole;
a conductive via disposed in the through-hole and protruding beyond the first insulating layer from both the first and second surfaces;
a first conductor layer disposed on the first surface of the first insulating layer and in contact with the conductive via; and
a second conductor layer disposed on the second surface of the first insulating layer and in contact with the conductive via,
wherein the conductive via protrudes beyond the inner conductor layer in both the upward and downward directions.

17. The printed circuit board of claim 16, wherein the inner conductor layer comprises a plated metal layer, and the conductive via comprises a conductive material that protrudes beyond the first and second surfaces of the first insulating layer.
